(19) United States
(12) Patent Application Publication
(10) Pub. No.: US 2025/0038091 A1
(43) Pub. Date: Jan. 30, 2025

(54) ELECTRONIC PACKAGING, MANUFACTURING METHOD FOR ELECTRONIC PACKAGING AND ELECTRONIC APPARATUS

(71) Applicant: CHENGDU HAIGUANG INTEGRATED CIRCUIT DESIGN CO., LTD., Sichuan (CN)

(72) Inventors: Shuan Du, Sichuan (CN); Xiaofeng Qian, Sichuan (CN); Xiaojun Yang, Sichuan (CN); Rui Guo, Sichuan (CN); Liu Yang, Sichuan (CN)

(21) Appl. No.: 18/696,611

(22) PCT Filed: Sep. 26, 2023
(86) PCT No.: PCT/CN2023/121380

§ 371 Date: Mar. 28, 2024

(30) Foreign Application Priority Data
Dec. 20, 2022 (CN) 202211646358.2

(51) Int. Cl. H01L 23/498; H01L 21/48; H01L 23/00; H01L 23/13; H01L 23/14; H01L 23/16; H01L 23/367; H01L 23/373; H01L 25/065; H05K 1/02

(52) U.S. Cl. CPC H01L 23/49833; H01L 21/4882; H01L 23/13; H01L 23/145; H01L 23/16; H01L 23/3677; H01L 23/49822; H01L 24/14; H01L 24/16; H05K 1/0204; H01L 23/3736; H01L 24/13; H01L 25/0655; H01L 2224/13147; H01L 2224/1403; H01L 2224/16225; H01L 2924/30101

(57) ABSTRACT

Embodiments of the present disclosure provide an electronic packaging, a manufacturing method for an electronic packaging and an electronic apparatus. The electronic packaging includes a package substrate and an interconnect substrate, wherein a first surface of the package substrate is provided with a recess in which the interconnect substrate is embedded; and a bottom of the interconnect substrate is provided with a first heat sink; the first surface of the package substrate is provided with a first die and a second die; the first die and the second die are electrically connected through the interconnect substrate.

### CROSS-REFERENCE TO RELATED APPLICATION(S)

The present application claims the priority of China Patent Application No. 202211646358.2 filed on Dec. 20, 2022, and the disclosure of the above-mentioned China Patent Application is hereby incorporated by reference in its entirety as a part of the present application.

### TECHNICAL FIELD

Embodiments of the present disclosure relate to an electronic packaging, a manufacturing method for an electronic packaging and an electronic apparatus.

### BACKGROUND

In electronic packaging, an embedded substrate can be arranged on a base substrate, and high-density interconnection between different dies can be realized through the embedded substrate.

Since signal lines on the embedded substrate usually are connected at a relatively greater density, it is easy to result in high temperature due to accumulation, which may affect a quality of signal transmission.

### SUMMARY

Embodiments of the present disclosure provide an electronic packaging, a manufacturing method for an electronic packaging, and an electronic apparatus, which facilitates improving the quality of signal transmission between dies.

In a first aspect of the present disclosure, an embodiment of the present disclosure provides an electronic packaging, including a package substrate and an interconnect substrate, wherein a first surface of the package substrate is provided with a recess in which the interconnect substrate is embedded; and a bottom of the interconnect substrate is provided with a first heat sink; the first surface of the package substrate is provided with a first die and a second die; the first die and the second die are electrically connected through the interconnect substrate.

According to a specific implementation of the embodiment of the present disclosure, the recess includes a first recess and a second recess, the first recess is connected with the second recess, and a width of the second recess is smaller than a width of the first recess; the first heat sink is supported in the second recess, at least part of the first heat sink is arranged in the first recess, and the interconnect substrate is arranged in the first recess and supported on the first heat sink.

According to a specific implementation of the embodiment of the present disclosure, the first heat sink includes a first thermal dissipation part and a second thermal dissipation part; the first thermal dissipation part is connected with the second thermal dissipation part, and a width of the second thermal dissipation part is smaller than a width of the first thermal dissipation part; the second thermal dissipation part is arranged in the second recess, and the first thermal dissipation part is arranged in the first recess and supported on a step at a transitional junction between the first recess and the second recess; and the interconnect substrate is supported on the first thermal dissipation part.

According to a specific implementation of the embodiment of the present disclosure, the second recess penetrates through a second surface of the package substrate.

According to a specific implementation of the embodiment of the present disclosure, further including a thermal dissipation hole, which is arranged in the second thermal dissipation part of the first heat sink at least along an axial direction of the first heat sink.

According to a specific implementation of the embodiment of the present disclosure, further including a stiffener ring arranged on the package substrate; the first die and the second die are arranged in a space surrounded by the stiffener ring.

According to a specific implementation of the embodiment of the present disclosure, further including a second heat sink supported on the stiffener ring, wherein the second heat sink corresponds to the first die and the second die.

According to a specific implementation of the embodiment of the present disclosure, the package substrate includes: a first interconnect layer, wherein the first recess is arranged in the first interconnect layer, and the first interconnect layer includes first metal wiring layers and first dielectric layers which are alternately stacked; the interconnect substrate includes: a second interconnect layer, including second metal wiring layers and second dielectric layers which are alternately stacked, wherein the second dielectric layer includes an organic material, and an arrangement density of the second metal wiring layers is greater than an arrangement density of the first metal wiring layers.

According to a specific implementation of the embodiment of the present disclosure, the organic material includes polyimide.

According to a specific implementation of the embodiment of the present disclosure, the package substrate further includes: a plurality of first connection bumps located on an upper surface of the first interconnect layer, wherein a first chip, a second chip and a third chip are electrically connected with the package substrate through the first connection bumps; the interconnect substrate further includes a plurality of second connection bumps located on an upper surface of the second interconnect layer, wherein a part of the first chip and a part of the second chip are electrically connected with the interconnect substrate through the second connection bumps.

According to a specific implementation of the embodiment of the present disclosure, a width of the second connection bump is smaller than a width of the first connection bump; and a distance between adjacent second connection bumps is smaller than a distance between adjacent first connection bumps.

In a second aspect, an embodiment of the present disclosure provides an electronic apparatus including the electronic packaging described in any of the first aspect, and a motherboard for the electronic packaging assembly, wherein the electronic packaging is electrically connected with the motherboard through the package substrate.

According to a specific implementation of the embodiment of the present disclosure, the motherboard is provided with a first through hole at a position corresponding to the recess.

According to a specific implementation of the embodiment of the present disclosure, the recess penetrates through a second surface of the package substrate and is connected with the first through hole.

According to a specific implementation of the embodiment of the present disclosure, the first heat sink is protruded into the first through hole from the package substrate.

In a third aspect, an embodiment of the present disclosure provides a manufacturing method for an electronic packaging, including providing a package substrate, and forming a recess on a first surface of the package substrate; providing a first heat sink, and embedding the first heat sink in the recess; providing an interconnect substrate, embedding the interconnect substrate in the recess, and arranging the interconnect substrate on the first heat sink; and providing at least two dies, and electrically connecting each of the at least two dies with the package substrate and the interconnect substrate, respectively.

According to a specific implementation of the embodiment of the present disclosure, the forming the recess on the first surface of the package substrate includes: forming a first recess on the first surface of the package substrate; and forming a second recess at a recess bottom of the first recess; wherein the first recess is connected with the second recess, and a width of the second recess is smaller than a width of the first recess.

According to a specific implementation of the embodiment of the present disclosure, the forming the second recess at the recess bottom of the first recess includes: forming the second recess penetrating through a second surface of the package substrate at the recess bottom of the first recess.

According to a specific implementation of the embodiment of the present disclosure, the method further includes: providing a stiffener ring and fixing the stiffener ring on the package substrate; and providing a second heat sink and supporting the second heat sink on the stiffener ring, wherein the second heat sink corresponds to the at least two dies.

### BRIEF DESCRIPTION OF DRAWINGS

In order to more clearly illustrate the technical solutions of the embodiments of the present disclosure, the drawings necessary for the description of the embodiments will be briefly described in the following; it is obvious that the described drawings are only related to some embodiments of the present disclosure, and other drawings can be obtained according to these drawings without creative work for those ordinary skilled in the art.

FIG. 1 is a schematic diagram of an electronic packaging in some embodiments of the present disclosure;

FIG. 2 is a schematic diagram of a second heat sink on a package substrate in some embodiments of the present disclosure;

FIG. 3 is a schematic diagram of an interconnect substrate in some embodiments of the present disclosure;

FIG. 4 is a schematic diagram of an electronic packaging in some other embodiments of the present disclosure;

FIG. 5 is a top view of a package substrate provided with a recess in some embodiments of the present disclosure;

FIG. 6 is a top view of a package substrate provided with a recess in some other embodiments of the present disclosure;

FIG. 7 is a schematic diagram of an electronic packaging in still some other embodiments of the present disclosure;

FIGS. 8A-8G are schematic diagrams of a manufacturing process for an electronic packaging in some embodiments of the present disclosure;

FIG. 9 is a flowchart of a manufacturing method for an electronic packaging in some embodiments of the present disclosure;

FIG. 10 is a schematic diagram of an electronic apparatus in some embodiments of the present disclosure;

FIG. 11 is a schematic diagram of an electronic apparatus in some other embodiments of the present disclosure; and

FIG. 12 is a schematic diagram of an electronic apparatus in still some other embodiments of the present disclosure.

### DETAILED DESCRIPTION

Hereinafter, the embodiments of the present disclosure will be described in details with reference to the accompanying drawings.

It should be clear that the described embodiments are only part of the embodiments of the present disclosure, but not all the embodiments. Based on the embodiments in the present disclosure, all other embodiments obtained by ordinary skilled in the art without creative work belong to the scope of protection of the present disclosure.

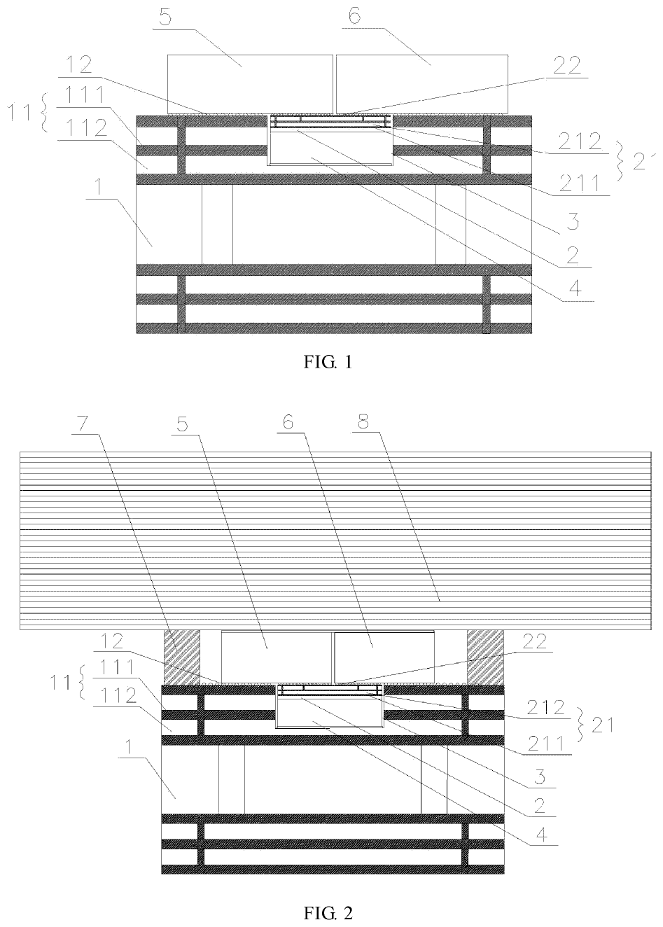

FIG. 1 is a schematic diagram of an electronic packaging in some embodiments of the present disclosure. Referring to FIG. 1, the electronic packaging provided by the embodiments of the present disclosure includes a package substrate 1 and an interconnect substrate 2; a recess 3 is arranged on a first surface of the package substrate 1, and the interconnect substrate 2 is embedded in the recess 3; a first heat sink 4 is arranged at a bottom of the interconnect substrate 2; a first die 5 and a second die 6 are arranged on the first surface of the package substrate 1; the first die 5 and the second die 6 are electrically connected through the interconnect substrate 2.

In some examples, the package substrate 1 may be an Ajinomoto Build-up Film substrate, which is abbreviated as ABF substrate in English. The recess 3 can be provided on the first surface (e.g., an upper surface) of the package substrate 1 by a photolithography process, a laser trenching process or the like. The package substrate 1 may further include an adhesive layer, which may be located between the first heat sink 4 and a bottom of the recess 3; and the bottom of the interconnect substrate 2 is fixed on the first heat sink 4 by means of the adhesive layer, so that the interconnect substrate 2 is embedded in the recess 3. The adhesive layer can be made of a double-sided die attach film (DAF). The first heat sink 4 can also be referred to as a first heat sink, a first thermal conductive member or the like. A material of the first heat sink 4 can be copper, aluminum alloy or the like.

In this embodiment, since the first heat sink 4 is arranged at the bottom of the interconnect substrate 2, it is convenient to dissipate heat from the interconnect substrate 2 through the first heat sink 4, which is beneficial to improving the quality of signal transmission between the first die 5 and the second die 6.

Moreover, with the decrease of the temperature of the interconnect substrate 2, heat would be transferred from a location with a higher temperature to a location with a lower temperature under a natural state, so that the heat on the first die 5 and the second die 6 can be transferred to the interconnect substrate 2, thereby reducing the temperature of the first die 5 and the second die 6, and also enabling the performance of the first die 5 and the second die 6 to be more stable.

FIG. 2 is a schematic diagram of a second heat sink 8 on the package substrate 1 in some embodiments of the present disclosure. Referring to FIG. 2, in an embodiment, the electronic packaging further includes a stiffener ring 7 arranged on the package substrate 1; the first die 5 and the second die 6 are arranged in a space surrounded by the stiffener ring 7.

The stiffener ring 7 is also referred to as a support ring. The stiffener ring 7 can be circular-shaped or rectangular-shaped, and a material of the stiffener ring 7 can be copper, aluminum alloy or the like. The stiffener ring 7 can be bonded and fixed onto the first surface of the package substrate 1 by means of a glue cured at high temperature, and can also be welded onto the first surface of the package substrate 1 by means of a solder. In order to further improve the thermal dissipation efficiency of the dies, referring to FIG. 2, in an embodiment, the electronic packaging further includes a second heat sink 8 supported on the stiffener ring 7, and the second heat sink 8 corresponds to the first die 5 and the second die 6; that is, the second heat sink 8 covers the first die 5 and the second die 6 from right above the first die 5 and the second die 6. In some examples, the second heat sink 8 may be a heat sink, such as a profiled heat sink, a stacked heat sink and the like. The second heat sink 8 can be press-fitted at the top of the stiffener ring 7 by a force clamp, and a height of the stiffener ring 7 can be slightly greater than a height of the first die 5 and the second die 6, so as to prevent the second heat sink 8 from compressing the first die 5 and the second die 6.

Heat generated by the first die 5 and the second die 6 can be dissipated from the top of the first die 5 and the top of the second die 6 through the second heat sink 8.

In this embodiment, heat can be dissipated from bottoms and tops of the first die 5 and the second die 6 by means of the first heat sink 4 at the bottom of the interconnect substrate 2 and the second heat sink 8 arranged at the tops of the first die 5 and the second die 6, respectively, thereby further improving the thermal dissipation efficiency for the first die 5 and the second die 6.

An incomplete contact may exist among the stiffener ring 7, the first die 5, the second die 6 and the second heat sink 8. When there is a certain gap among the stiffener ring 7, the first die 5, the second die 6 and the second heat sink 8, a large thermal resistance may exist. In some examples, a thermal conductive material (not shown in the figure) can be arranged among the stiffener ring 7, the first die 5, the second die 6 and the second heat sink 8, which can effectively reduce the thermal resistance among the stiffener ring 7, the first die 5, the second die 6 and the second heat sink 8. In this way, the heat generated by the stiffener ring 7, the first die 5 and the second die 6 can be quickly transferred to the second heat sink 8. The thermal conductive material can be thermal conductive silicone grease, thermal conductive paste or the like.

The first die 5 and the second die 6 are located in a closed space surrounded by the interconnect substrate 2, the stiffener ring 7, the thermal conductive material and the second heat sink 8 on the package substrate 1. In some examples, the stiffener ring 7, the thermal conductive material and the second heat dissipating member 8 can not only dissipate heat from the first die 5 and the second die 6, but also protect the first die 5 and the second die 6.

In some embodiments, the package substrate 1 includes a first interconnect layer 11 in which the first recess 31 is arranged, and the first interconnect layer 11 includes first metal wiring layers 111 and first dielectric layers 112 which are alternately stacked; the interconnect substrate 2 includes a second interconnect layer 21, and the second interconnect layer 21 includes second metal wiring layers and second dielectric layers which are alternately stacked; the second dielectric layer includes an organic material, and an arrangement density of the second metal wiring layers is greater than an arrangement density of the first metal wiring layers 111.

The arrangement density refers to a line spacing between two adjacent metal traces. It can be seen that the wirings on the interconnect substrate 2 is denser than that on the package substrate 1, which can realize high-density interconnection of signal lines between the first die 5 and the second die 6 and is convenient to increase a bandwidth of signal transmission, thus reducing a delay of signal transmission between the first die 5 and the second die 6 and reducing an overall energy consumption.

In some examples, in the first metal wiring layer 111, a line width and a line spacing of metal lines can be 12 um, respectively; in the second metal wiring layer, a width of a single metal trace is 0.5 um-5 um, and a spacing between two adjacent metal traces is 0.5 um-5 um.

In some embodiments, the organic material includes polyimide, so that when the interconnect substrate 2 is machined, there is no need to adopt a traditional silicon process for the processing equipment and the processing environment, thus reducing the production cost.

In some embodiments, the package substrate 1 further includes a plurality of first connection bumps 12 located on an upper surface of the first interconnect layer 11, and the first die 5 and the second die 6 are electrically connected with the package substrate 1 through the first connection bumps 12; the interconnect substrate 2 further includes a plurality of second connection bumps located on an upper surface of the second interconnect layer 21, and a part of the first die 5 and a part of the second die 6 are electrically connected with the interconnect substrate 2 through the second connection bumps.

In some examples, the first connection bump 12 and the second connection bump may be spherical-shaped connection bumps. The first connection bump 12 may include a first copper pillar and a first solder ball arranged at the end of the first copper pillar; and the first copper pillar is electrically connected with the first interconnect layer 11 on the package substrate 1. The second connection bump may include a second copper pillar and a second solder ball arranged at the end of the second copper pillar; and the second copper pillar is electrically connected with the second interconnect layer 21 on the interconnect substrate 2.

In some examples, the first die 5 may include a third connection bump (not shown in the figure) corresponding to the first connection bump 12, and the third connection bump may include a third copper pillar and a third solder ball arranged at the end of the third copper pillar. By soldering the third solder ball and the first solder ball one by one, the first die 5 can be electrically connected with the package substrate 1. The first die 5 may further include a fourth connection bump (not shown in the figure) corresponding to the second connection bump, and the fourth and third connection bumps are located in different areas on a same surface of the first die 5. The fourth connection bump may include a fourth copper pillar and a fourth solder ball arranged at the end of the fourth copper pillar. By soldering the fourth solder ball and the second solder ball one by one, the first die 5 can be electrically connected with the interconnect substrate 2.

In some examples, the second die 6 may include a fifth connection bump (not shown in the figure) corresponding to the first connection bump 12, and the fifth connection bump may include a fifth copper pillar and a fifth solder ball arranged at the end of the fifth copper pillar. By soldering the fifth solder ball and the first solder ball one by one, the second die 6 can be electrically connected with the package substrate 1. The second die 6 may also include a sixth connection bump (not shown in the figure) corresponding to the second connection bump, and the sixth and fifth connection bumps are located in different areas on a same surface of the second die 6. The sixth connection bump may include a sixth copper pillar and a sixth solder ball arranged at the end of the sixth copper pillar. By soldering the sixth solder ball and the second solder ball one by one, the second die 6 can be electrically connected with the interconnect substrate 2.

In some embodiments, at least one of the following is satisfied between the second connection bump and the first connection bump 12: a width of the second connection bump (in a direction parallel to the base substrate) is smaller than a width of the first connection bump 12; and a distance between adjacent second connection bumps is smaller than a distance between adjacent first connection bumps 12.

In some examples, the width of the second connection bump is smaller than the width of the first connection bump 12, which may be the case that a diameter of the second connection bump is smaller than a diameter of the first connection bump 12.

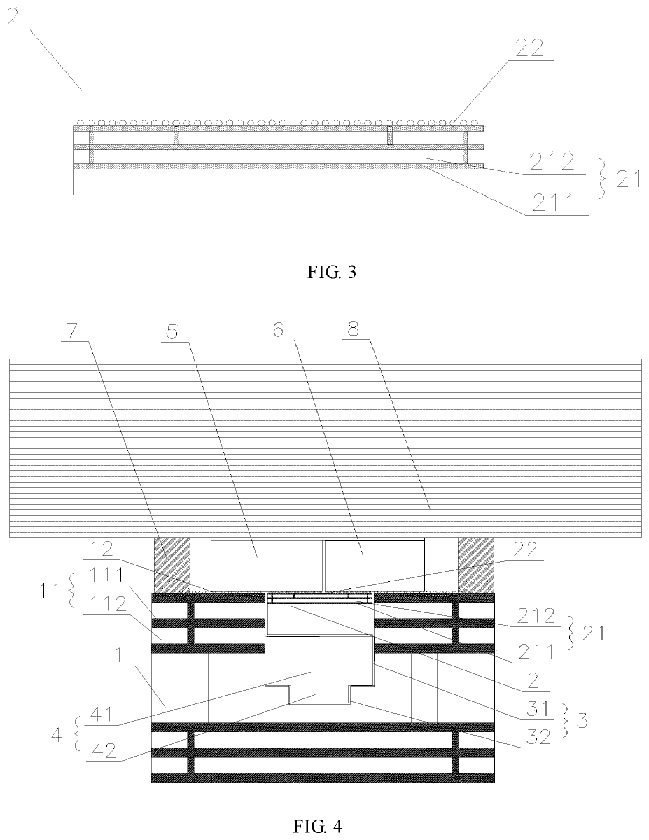

FIG. 4 is a schematic diagram of an electronic packaging in some embodiments of the present disclosure. Referring to FIG. 4, the electronic packaging of this embodiment has a structure basically the same as that of the embodiment shown in FIG. 2, except that in the electronic packaging of this embodiment, the recess 3 on the package substrate 1 may include a first recess 31 and a second recess 32 connected with each other, and a width (in a direction parallel to the base substrate) of the second recess 32 is smaller than a width of the first recess 31; the first heat sink 4 is supported in the second recess 32, and at least part of the first heat sink 4 is arranged in the first recess 31, and the interconnect substrate 2 is arranged in the first recess 31 and supported on the first heat sink 4.

In some examples, the width of the second recess 32 is smaller than the width of the first recess 31, which may be the case that a cross-sectional area of the second recess 32 is smaller than a cross-sectional area of the first recess 31. The cross-sectional area refers to the cross-sectional area perpendicular to a central axis thereof.

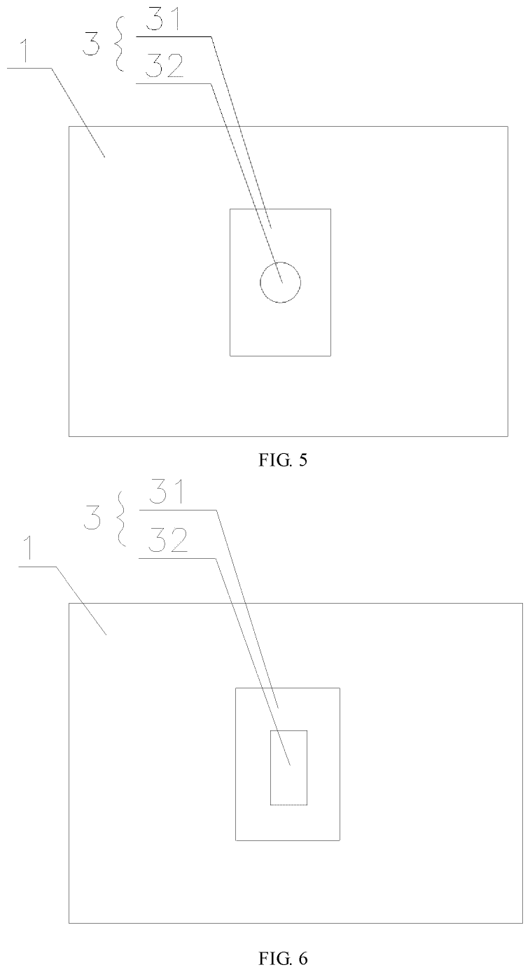

The second recess 32 is located below the first recess 31; and the second recess 32 and the first recess 31 may have a same shape or have different shapes. Referring to FIG. 5, the second recess 32 is cylindrical-shaped, and the first recess 31 is rectangular-shaped. Referring to FIG. 6, both the second recess 32 and the first recess 31 are rectangular-shaped.

An accuracy of the second recess 32 may be smaller than an accuracy of the first recess 31. The first recess 31 can be formed on the first surface of the package substrate 1 by a photolithography process, a laser trenching process or the like, so that the first recess 31 is a high-precision recess 3; the second recess 32 can be formed at a recess bottom of the first recess 31 by way of mechanical processing, such as a milling process.

By forming the second recess 32 at the recess bottom of the first recess 31, a volume of the first heat sink 4 can be increased, and the heat absorption capacity of the first heat sink 4 can be improved. The first heat sink 4 can absorb the heat conducted to the interconnect substrate 2 by the first die 5 and the second die 6, and can also absorb the heat generated by the package substrate 1 at the same time, thereby serving for thermal dissipation of the package substrate 1 as well. In addition, since the width of the second recess 32 is smaller than that of the first recess 31, by supporting the first heat sink 4 in the second recess 32, the installation and positioning during placing the first heat sink 4 in the recess 3 can be facilitated.

In some examples, referring to FIG. 4, the first heat sink 4 includes a first thermal dissipation part 41 and a second thermal dissipation part 42, the first thermal dissipation part 41 is connected with the second thermal dissipation part 42, and a width of the second thermal dissipation part 42 is smaller than a width of the first thermal dissipation part 41; the second thermal dissipation part 42 is arranged in the second recess 32, and the first thermal dissipation part 41 is arranged in the first recess 31 and supported on a stair at a transitional junction between the first recess 31 and the second recess 32; the interconnect substrate 2 is supported on the first thermal dissipation part 41.

The width of the second thermal dissipation part 42 is smaller than the width of the first thermal dissipation part 41, which may be the case that a cross-sectional area of the second thermal dissipation part 42 perpendicular to a central axis thereof is smaller than a cross-sectional area of the first thermal dissipation part 41 perpendicular to a central axis thereof. The first heat sink 4 can be fabricated by one-piece molding process.

A shape of the second thermal dissipation part 42 can be adapted to a shape of the second recess 32; and a shape of the first thermal dissipation part 41 can be adapted to a shape of the first recess 31.

A stair surface at a transitional junction between the second thermal dissipation part 42 and the first thermal dissipation part 41 of the first heat sink 4 can be bonded onto the stair at the transitional junction between the first recess 31 and the second recess 32 by using a double-sided die attach film (DAF), which is then cured there at high temperature.

In this embodiment, the first heat sink 4 includes a first thermal dissipation part 41 and a second thermal dissipation part 42; the second thermal dissipation part 42 is arranged in the second recess 32, and the first thermal dissipation part 41 is arranged in the first recess 31 and supported on the stair at the transitional junction between the first recess 31 and the second recess 32. In this way, a contact area between the first heat sink 4 and the package substrate 1 can be increased; correspondingly, the first thermal dissipation part 41 can absorb the heat generated by the package substrate 1 more effectively at the same time when absorbing the heat conducted to the interconnect substrate 2 through the first die 5 and the second die 6, so that a better thermal dissipation effect for the package substrate 1 and the interconnect substrate 2 can be achieved.

A thermal conductive material, such as thermal conductive silicone grease and thermal conductive paste, may be provided at the top of the first thermal dissipation part 41, so as to improve the thermal dissipation efficiency for the interconnect substrate 2.

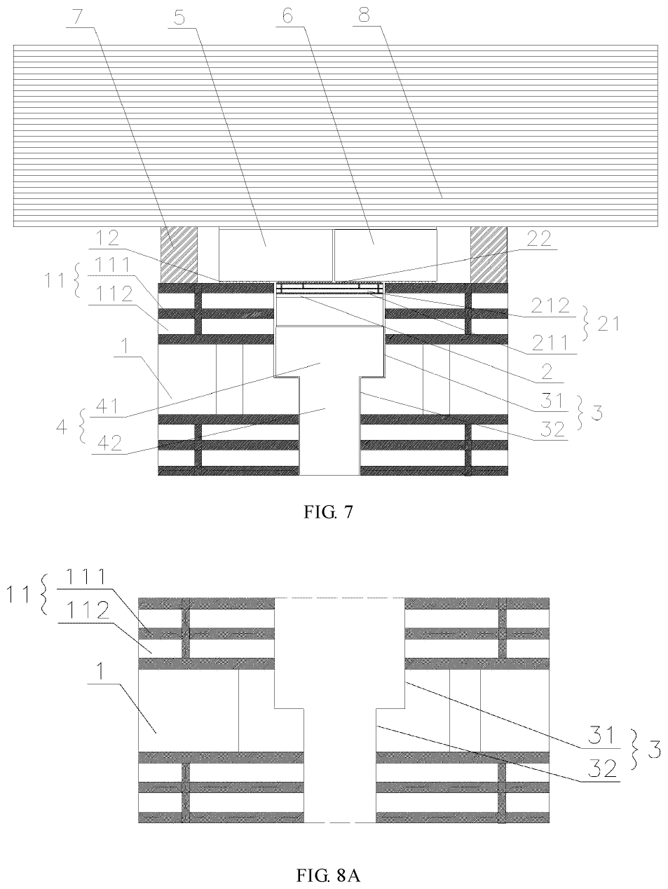

FIG. 6 is a schematic diagram of an electronic packaging in some embodiments of the present disclosure. Referring to FIG. 7, the electronic packaging of this embodiment has a structure basically the same as that shown in FIG. 2, except that in the electronic packaging of this embodiment, the second recess 32 penetrates through a second surface of the package substrate 1 in addition to the second recess 32 being connected with the first recess 31.

In this embodiment, the second thermal dissipation part 42 of the first heat sink 4 located in the second recess 32 penetrates through the second surface of the package substrate 1, and can dissipate the heat absorbed by the first heat sink 4 to the outside of the package substrate 1, so as to further enhance the thermal dissipation effect of the first heat sink 4 for the interconnect substrate 2 (the heat of the interconnect substrate 2 mainly comes from the first die 5 and the second die 6) and the package substrate 1, thereby improving the thermal dissipation efficiency for the first die 5 and the second die 6.

In an embodiment, the electronic packaging further includes a thermal dissipation hole, which is arranged in the second thermal dissipation part 42 of the first heat sink 4 at least along an axial direction of the first heat sink 4.

The electronic packaging may include a plurality of thermal dissipation holes. The plurality of thermal dissipation holes can be blind holes, and a length of each thermal dissipation hole can penetrate deeply into the first thermal dissipation part 41. In this way, cold air can enter the thermal dissipation holes and take away the heat absorbed by the first heat sink 4. In an example, the plurality of thermal dissipation holes may include a first thermal dissipation hole and a second thermal dissipation hole, and ends of the first thermal dissipation hole and the second thermal dissipation hole that penetrate deeply into the first thermal dissipation part 41 are connected with each other, thus facilitating the formation of a convection channel for cold air and improving the thermal dissipation efficiency.

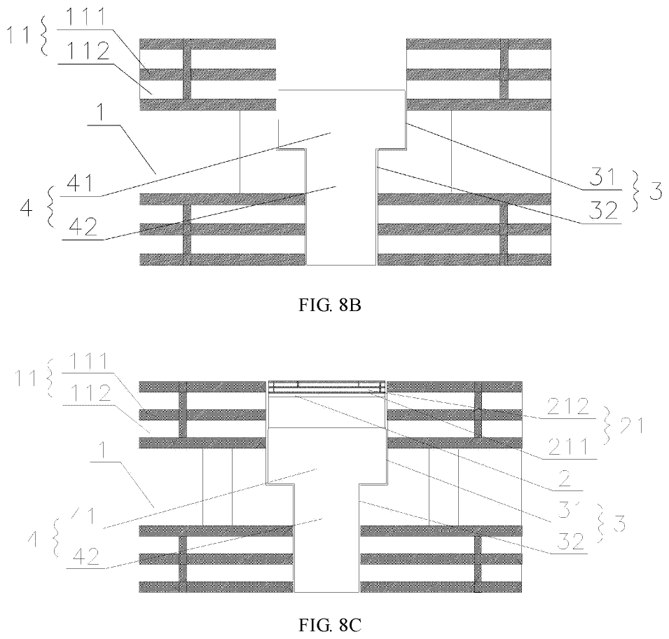

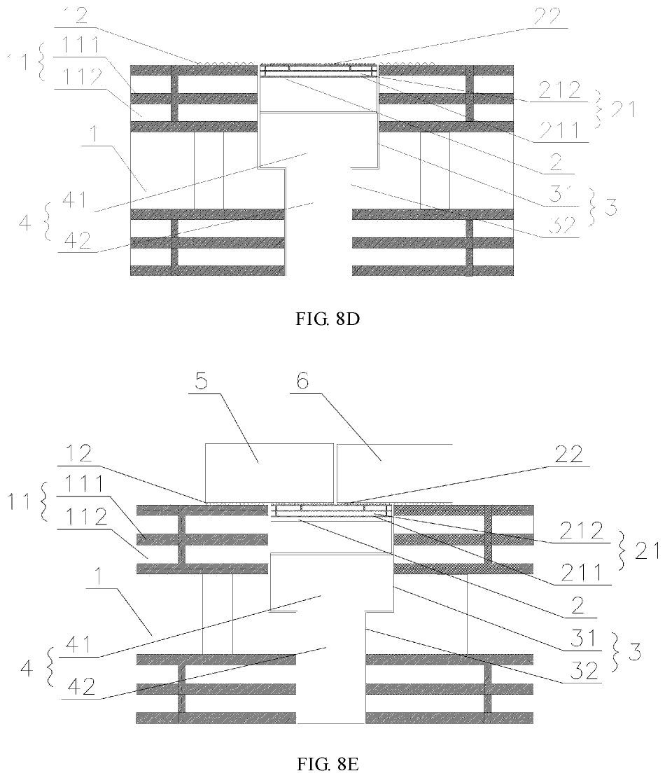

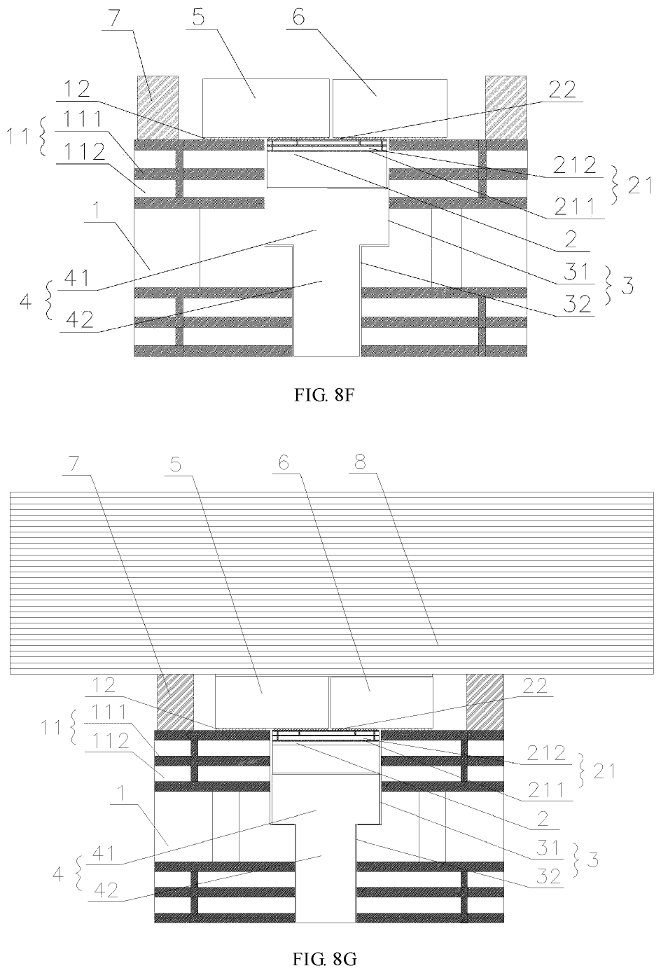

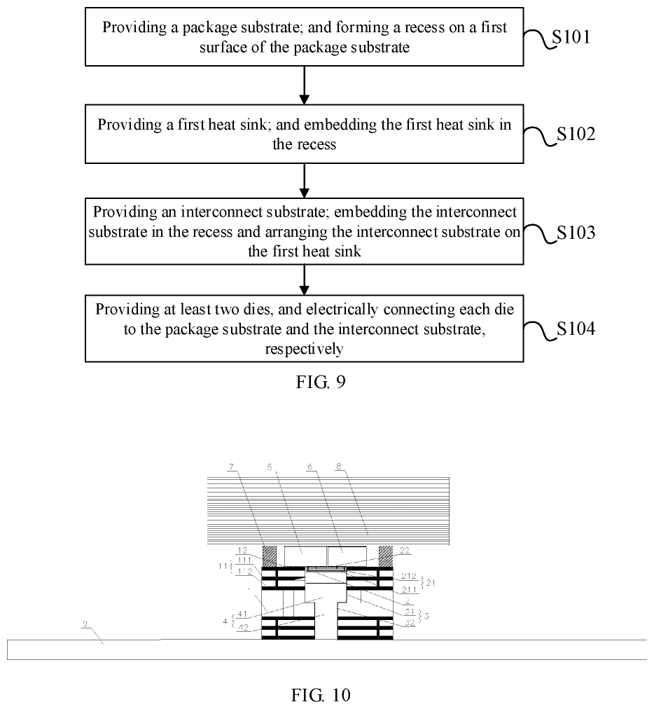

An embodiment of the present disclosure provides a manufacturing method for an electronic packaging, which is used for manufacturing the electronic packaging described above. As shown in FIGS. 8A to 8G and FIG. 9, the manufacturing method includes the following steps.
S101, providing a package substrate 1; and forming a recess 3 on a first surface of the package substrate 1.

As an alternative embodiment, forming the recess 3 on the first surface of the package substrate 1 (S101) may include:
S1011, forming a first recess 31 on the first surface of the package substrate 1;
S1012, forming a second recess 32 at a recess bottom of the first recess 31; wherein the first recess 31 is connected with the second recess 32, and a width of the second recess 32 is smaller than a width of the first recess 31.
S102, providing a first heat sink 4; and embedding the first heat sink 4 in the recess 3;
S103, providing an interconnect substrate 2; embedding the interconnect substrate 2 in the recess 3 and arranging the interconnect substrate 2 on the first heat sink 4;
S104, providing at least two dies, and electrically connecting each die to the package substrate 1 and the interconnect substrate 2, respectively.

For specific processing steps corresponding to this step, reference can be made to FIGS. 8A to 8E.

A first recess 31 can be formed on the first surface of the package substrate 1 by a photolithography process, and a second recess 32 can be formed at the recess bottom of the first recess 31 by a milling process. The second recess 32 penetrates through the second surface of the package substrate 1, as shown in FIG. 8A, in which a cross-sectional area of the second recess 32 perpendicular to a central axis thereof is smaller than a cross-sectional area of the first recess 31 perpendicular to a central axis thereof.

A double-sided die attach film (DAF) can be bonded onto a stair at a transitional junction between the first recess 31 and the second recess 32, and the second thermal dissipation part 42 of the first heat sink 4 can be put into the second recess 32 after passing through the first recess 31, so that a bottom of the first thermal dissipation part 41 of the first heat sink 4 can be bonded with the aforementioned stair through the double-sided die attach film (DAF), which is then cured at high temperature, as shown in FIG. 8B, in which the top of the first thermal dissipation part 41 is kept in a horizontal direction.

A double-sided die attach film (DAF) with high thermal conductivity can be bonded onto the top of the first thermal dissipation part 41, and the interconnect substrate 2 can be placed in the first recess 31, so that the interconnect substrate 2 can be bonded with the top of the second heat sink 8 through the double-sided die attach film (DAF) with high thermal conductivity, which is then cured at high temperature, as shown in FIG. 8C.

Copper pillars and solder balls can be electroplated onto the package substrate 1 and the interconnect substrate 2 to obtain a first connection bump 12, a second connection bump, a third connection bump and a fourth connection bump, as shown in FIG. 8D, in which the first connection bump 12 is electrically connected with a second connection layer, the second connection bump is electrically connected with a third connection layer, the third connection bump is electrically connected with a first end of a first connection layer, and the fourth connection bump is electrically connected with a second end of the first connection layer.

By means of a reflow soldering process, a first part of the first die 5 can be electrically connected with the third connection bump, a second part of the first die 5 can be electrically connected with the first connection bump 12, a first part of the second die 6 can be electrically connected with the fourth connection bump, and a second part of the second die 6 can be electrically connected with the second connection bump, as shown in FIG. 8E.

In some examples, the package substrate 1 and the interconnect substrate 2 are cleaned and dried, and the above-described first connection bump 12, second connection bump, third connection bump and fourth connection bump are underfilled with an underfill glue.

In the manufacturing method for the electronic packaging of the embodiments of the present disclosure, since the first heat sink 4 is arranged at the bottom of the interconnect substrate 2, it is convenient to dissipate heat from the interconnect substrate 2 through the first heat sink 4, which is beneficial to improving the quality of signal transmission between the first die 5 and the second die 6.

In addition, as the decrease of the temperature of the interconnect substrate 2, heat will be transferred from a location with a higher temperature to a location with a lower temperature under a natural state, so that the heat on the first die 5 and the second die 6 can be transferred to the interconnect substrate 2, thereby lowering the temperature of the first die 5 and the second die 6 and enabling the performance of the first die 5 and the second die 6 to be more stable.

In some embodiments, forming the second recess 32 at the recess bottom of the first recess 31 includes: forming the second recess 32 penetrating through the second surface of the package substrate 1 at the recess bottom of the first recess 31.

As mentioned above, in this embodiment, by forming the second recess 32 penetrating through the second surface of the package substrate 1, the second thermal dissipation part 42 of the first heat sink 4 located in the second recess 32 can penetrate through the second surface of the package substrate 1, so that the heat absorbed by the first heat sink 4 can be dissipated to the outside of the package substrate 1 to further enhance the thermal dissipation effect of the first heat sink 4 for the interconnect substrate 2 (the heat of the interconnect substrate 2 mainly comes from the first die 5 and the second die 6) and the package substrate 1, thereby improving the thermal dissipation efficiency for the first die 5 and the second die 6.

In some embodiments, after the first die 5 and the second die 6 are arranged on the package substrate 1, the method further includes: providing a stiffener ring 7; fixing the stiffener ring 7 on the package substrate 1; providing a second heat sink 8 and supporting the second heat sink 8 on the stiffener ring 7, in which the second heat sink 8 corresponds to the at least two dies.

For specific processing steps corresponding to this step, reference can be made to FIGS. 8F to 8G.

An adhesive glue is coated at a position where the stiffener ring 7 is to be placed on the package substrate 1, then the stiffener ring 7 is placed on the package substrate 1 and is bonded with the package substrate 1 through the adhesive glue which is cured at high temperature, as shown in FIG. 8F.

The tops of the stiffener ring 7, the first die 5 and the second die 6 are coated with thermal conductive silicone grease or graphene or indiums; the second heat sink 8 is placed on the tops of the stiffener ring 7, the first die 5 and the second die 6 from above of the first die 5 and the second die 6; and the second heat sink 8 is pressed to be in close and tight contact with the tops of the stiffener ring 7, the first die 5 and the second die 6 through force clamps, as shown in FIG. 8G.

In this embodiment, by means of the first heat sink 4 at the bottom of the interconnect substrate 2 and the second heat sink 8 arranged at the tops of the first die 5 and the second die 6, heat can be dissipated from the bottom and the top of the first die 5 and of the second die 6, and the thermal dissipation efficiency for the first die 5 and the second die 6 is further improved.

FIG. 10 is a schematic diagram of an electronic apparatus in some embodiments of the present disclosure. Referring to FIG. 10, this embodiment provides an electronic apparatus including the electronic packaging described in any of the previous embodiments; and a motherboard 9 for an assembly of the electronic packaging; the electronic packaging is electrically connected with the motherboard 9 through the package substrate 1. The motherboard 9 can also be referred to as a master board or a main board, and a plurality of electronic packages can be arranged on the motherboard 9. The beneficial effects of the electronic apparatus in this embodiment are basically the same as those of the electronic packaging therein, which will not be repeated here.

Referring to FIG. 10, in an example, the motherboard 9 is provided with a first through hole 10 at a position corresponding to the recess 3. Air convection can be formed in the first through hole 10, so that cold air can continuously flow into the first through hole 10, and hot air in the first through hole 10 can be continuously exhausted, thereby achieving a thermal dissipation of the package substrate 1. Since an air convection can be formed in the first through hole 10 to reduce the temperature of the package substrate 1, a temperature difference between the package substrate 1 and the first heat sink 4 can be increased, so that the first through hole 10 can enhance the thermal dissipation effect of the first heat sink 4 for the interconnect substrate 2.

Further, a fan may be provided at a side of the motherboard 9 where the electronic packaging is not provided, so as to enhance the air convection effect in the first through hole 10, thereby improving the thermal dissipation effect of the first heat sink 4 for the interconnect substrate 2.

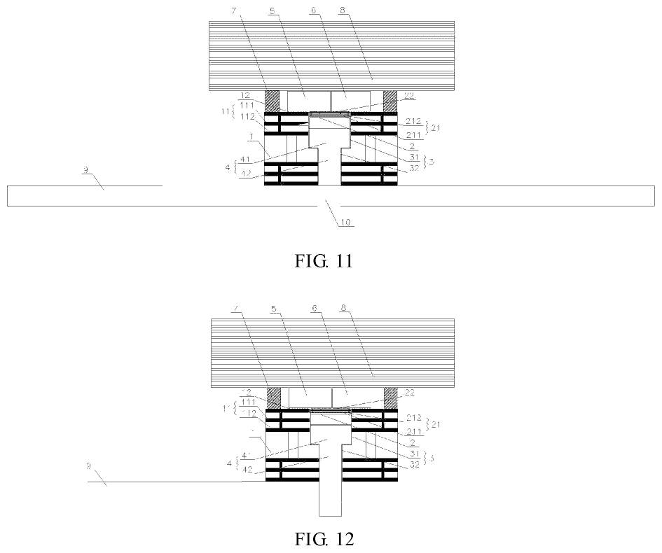

FIG. 11 is a schematic diagram of an electronic apparatus in some embodiments of the present disclosure. Referring to FIG. 11, in an example, the recess 3 penetrates through the second surface of the package substrate 1 and is connected with the first through hole 10, so that the airflow entering the first through hole 10 directly contacts with the first heat sink 4 to provide thermal dissipation efficiency of the first heat sink 4.

FIG. 12 is a schematic diagram of an electronic apparatus in some embodiments of the present disclosure. Referring to FIG. 12, further to the example shown in FIG. 11, the first heat sink 4 can be protruded into the first through hole 10 from the package substrate 1. In this way, a volume of the first heat sink 4 can be increased to enhance the thermal dissipation effect of the first heat sink 4 for the interconnect substrate 2. Referring to FIG. 12, a length of the second thermal dissipation part 42 of the first heat sink 4 can also extend out of the first through hole 10 to increase a contact area with cold air, and to further enhance the thermal dissipation effect.

It should be noted that in the present disclosure, solutions described among various embodiments are focused differently, but there is a certain correlation between the various embodiments, which can be used for reference when understanding the disclosed solution; in addition, relational terms such as first and second are only used to distinguish one entity or operation from another entity or operation, and do not necessarily require or imply any such actual relationship or order between these entities or operations. Moreover, the terms “including”, “comprising” or any other variations thereof are intended to cover non-exclusive inclusions, so that a process, method, article or equipment including a series of elements includes not only those elements, but also other elements not explicitly listed or elements inherent to such process, method, article or equipment. Without further restrictions, an element defined by the phrase “including one . . . ” does not exclude the existence of other identical elements in the process, method, article or equipment including the element.

The above is only the specific implementation of the present disclosure, but the scope of protection of the present disclosure is not limited thereto. Any change or replacement that can be easily conceived of by a skilled person familiar with this technical field within the technical scope disclosed in the present disclosure should be included in the scope of protection of the present disclosure. Therefore, the scope of protection of the present disclosure should be determined based on the scope of protection of the appended claims.

1. An electronic packaging, comprising:
a package substrate and an interconnect substrate, wherein:
a first surface of the package substrate is provided with a recess in which the interconnect substrate is embedded; and
a bottom of the interconnect substrate is provided with a first heat sink;
the first surface of the package substrate is provided with a first die and a second die; and
the first die and the second die are electrically connected through the interconnect substrate.

2. The electronic packaging according to claim 1, wherein:
the recess comprises a first recess and a second recess, the first recess is connected with the second recess, and a width of the second recess is smaller than a width of the first recess;
the first heat sink is supported in the second recess, at least part of the first heat sink is arranged in the first recess, and the interconnect substrate is arranged in the first recess and supported on the first heat sink.

3. The electronic packaging according to claim 2, wherein:
the first heat sink comprises a first thermal dissipation part and a second thermal dissipation part;
the first thermal dissipation part is connected with the second thermal dissipation part, and a width of the second thermal dissipation part is smaller than a width of the first thermal dissipation part;
the second thermal dissipation part is arranged in the second recess, and the first thermal dissipation part is arranged in the first recess and supported on a stair at a transitional junction between the first recess and the second recess; and
the interconnect substrate is supported on the first thermal dissipation part.

4. The electronic packaging according to claim 3, wherein the second recess penetrates through a second surface of the package substrate.

5. The electronic packaging according to claim 3, further comprising a thermal dissipation hole, which is arranged in the second thermal dissipation part of the first heat sink at least along an axial direction of the first heat sink.

6. The electronic packaging according to claim 1, further comprising a stiffener ring arranged on the package substrate; and wherein the first die and the second die are arranged in a space surrounded by the stiffener ring.

7. The electronic packaging according to claim 6, further comprising a second heat sink supported on the stiffener ring, wherein the second heat sink corresponds to the first die and the second die.

8. The electronic packaging according to claim 2, wherein:
the package substrate comprises:
a first interconnect layer, wherein the first recess is arranged in the first interconnect layer, and the first interconnect layer comprises first metal wiring layers and first dielectric layers which are alternately stacked; and
the interconnect substrate comprises:
a second interconnect layer, comprising second metal wiring layers and second dielectric layers which are alternately stacked, wherein the second dielectric layer comprises an organic material, and an arrangement density of the second metal wiring layers is greater than an arrangement density of the first metal wiring layers.

9. The electronic packaging according to claim 8, wherein the organic material comprises polyimide.

10. The electronic packaging according to claim 8, wherein:
the package substrate further comprises a plurality of first connection bumps located on an upper surface of the first interconnect layer, wherein a first chip, a second chip and a third chip are electrically connected with the package substrate through the first connection bumps; and
the interconnect substrate further comprises a plurality of second connection bumps located on an upper surface of the second interconnect layer, wherein a part of the first chip and a part of the second chip are electrically connected with the interconnect substrate through the second connection bumps.

11. The electronic packaging according to claim 10, wherein,
a width of the second connection bump is smaller than a width of the first connection bump; and/or
a distance between adjacent second connection bumps is smaller than a distance between adjacent first connection bumps.

12. An electronic apparatus, comprising the electronic packaging according to claim 1, and a motherboard for an assembly of the electronic packaging,
wherein the electronic packaging is electrically connected with the motherboard through the package substrate.

13. The electronic apparatus according to claim 12, wherein the motherboard is provided with a first through hole at a position corresponding to the recess.

14. The electronic apparatus according to claim 13, wherein the recess penetrates through a second surface of the package substrate and is connected with the first through hole.

15. The electronic apparatus according to claim 14, wherein the first heat sink is protruded into the first through hole from the package substrate.

16. A manufacturing method for an electronic packaging, comprising:
providing a package substrate, and forming a recess on a first surface of the package substrate;
providing a first heat sink, and embedding the first heat sink in the recess;
providing an interconnect substrate, embedding the interconnect substrate in the recess, and arranging the interconnect substrate on the first heat sink; and
providing at least two dies, and electrically connecting each of the at least two dies with the package substrate and the interconnect substrate, respectively.

17. The manufacturing method for an electronic packaging according to claim 16, wherein:
the forming the recess on the first surface of the package substrate comprises:
forming a first recess on the first surface of the package substrate, and
forming a second recess at a recess bottom of the first recess; and
wherein the first recess is connected with the second recess, and a width of the second recess is smaller than a width of the first recess.

18. The manufacturing method for an electronic packaging according to claim 17, wherein the forming the second recess at the recess bottom of the first recess comprises:
forming the second recess penetrating through a second surface of the package substrate at the recess bottom of the first recess.

19. The manufacturing method for an electronic packaging according to claim 16, further comprising:
providing a stiffener ring and fixing the stiffener ring on the package substrate; and
providing a second heat sink and supporting the second heat sink on the stiffener ring,
wherein the second heat sink corresponds to the at least two dies.
